(19) United States
(12) Patent Application Publication
(10) Pub. No.: US 2004/0264145 A1
(43) Pub. Date: Dec. 30, 2004

(54) Compact electronic component system and method

(76) Inventors: Greg F. Miller, San Diego, CA (US); David Driggers, San Diego, CA (US); Victor Hester, El Cajon, CA (US); John V. Smith, Poway, CA (US); Luke Pniak, Lemon Grove, CA (US)

Correspondence Address: DUCKOR SPRADLING METZGER, 401 WEST A STREET, SUITE 2400, SAN DIEGO, CA, 92101-7915, US

(21) Appl. No.: 10/841,712

(22) Filed: May 6, 2004

Related U.S. Application Data
(60) Provisional application No. 60/469,267, filed on May 8, 2003.

(51) Int. Cl. H05K 7/16

(52) U.S. Cl. 361/725

(57) ABSTRACT

According to one of the disclosed embodiments of the invention, a compact electronic computer unit is provided and includes a frame having rack mounts for connection with a rack, and adapted to store a plurality of electronic components, which are supported within the frame in a generally upright disposition in a side-by-side configuration.

### RELATED APPLICATIONS

This application claims priority to the following U.S. provisional application, Application No. 60/469,267, filed May 8, 2003, and entitled Compact Electronic Component System and Method.

This application claims priority to the following U.S. design application, application Ser. No. 29/180,526, filed Apr. 25, 2003, and entitled Electronic Component Housing Front Panel.

This application claims priority to the following U.S. non-provisional applications:

| Title | Serial No. | Filed |
|---|---|---|
| Rack Mountable Computer Component | 10/449,799 | May 29, 2003 |
| and Method of Making Same | | |
| Rack Mountable Computer Component | 10/448,691 | May 29, 2003 |
| Cooling Method and Device | | |
| Rack Mountable Computer Fan Cooling | 10/449,608 | May 29, 2003 |
| Arrangement Method | | |
| Rack Mountable Component Power | 10/448,508 | May 29, 2003 |
| Distribution Unit and Method | | |
| Portable Diagnostic Apparatus for | 10/655,862 | Sep. 5, 2003 |
| Computer Components and Systems | | |
| and Method of Using Same | | |
| Control System and Method for Rack | 10/656,024 | Sep. 5, 2003 |
| Mounted Computer Units | | |
| Electronic Component Rack Assembly | 10/658,440 | Sep. 8, 2003 |
| and Method | | |

This application is related to the following U.S. provisional applications:

| | Application | |
|---|---|---|
| Title | No. | Filed |
| Rack Mountable Computer Component | 60/384,996 | May 31, 2002 |
| and Method of Making Same | | |
| Rack Mountable Computer Component | 60/384,987 | May 31, 2002 |
| Cooling Method and Device | | |
| Rack Mountable Computer Component | 60/384,986 | May 31, 2002 |
| Fan Cooling Arrangement and Method | | |
| Portable Diagnostic Apparatus for | 60/411,850 | Sep. 18, 2002 |
| Computer Components and Systems | | |
| and Method of Using Same | | |
| Remote Reset System and Method for | 60/413,922 | Sep. 25, 2002 |
| Computer Components and Systems | | |
| Rack Mountable Computer Component | 60/385,005 | May 31, 2002 |
| Power Distribution Unit and Method | | |
| Method and Apparatus for Rack | 60/413,803 | Sep. 25, 2002 |
| Mounting Computer Components | | |

This application is related to the following U.S. non-provisional application, application Ser. No. 10/160,526, filed May 31, 2002, and entitled Method and Apparatus for Rack Mounting Computer Components.

The foregoing U.S. provisional and non-provisional applications are incorporated herein by reference as if fully set forth herein in their entirety.

### FIELD OF THE INVENTION

The present invention relates in general to a compact electronic component system and method. The invention more particularly relates to a system and method for housing electronic components in a convenient compact manner.

### BACKGROUND ART

There have been a variety of different techniques employed in connection with the housing of electronic components in a convenient and compact manner. For example, rack mounted computers are conventionally mounted in horizontal arrays in racks. Such arrangements typically have cable connections where the cables are positioned in a back plane. It has also been proposed to mount the electronic components in a vertical disposition to have a more compact design.

### DESCRIPTIONS OF THE DRAWINGS

The following is a brief description of the drawings:

FIG. 1 is a pictorial view of a compact electronic component system, which is constructed in accordance with an embodiment of the invention;

FIG. 2 is a front elevational view of the system of FIG. 1;

FIG. 3 is a reduced-scale exploded view of the system of FIG. 1;

FIG. 4 is an enlarged-scale pictorial view of the system of FIG. 1, illustrating it partially disassembled;

FIG. 5 is a vertical sectional view of the system of FIG. 1, illustrating one example of an air flow path;

FIG. 6 is a vertical sectional view of the system of FIG. 1, illustrating a different air flow path according to an embodiment of the inventions;

FIG. 7 is a pictorial view, which is similar to the view of FIG. 4, except that the front panel is removed;

FIG. 8 is a pictorial view of the system of FIG. 1, illustrating it with the front panels removed for illustration purposes;

FIG. 9 is an enlarged pictorial view of a component of the system of FIG. 1;

FIG. 10 is an enlarged pictorial view of another component of the system of FIG. 1;

FIG. 11 is an enlarged pictorial view of another component of the system of FIG. 1;

FIG. 12 is a reduced-scale pictorial view, which is similar to the view of FIG. 7, with the internal electronic components removed for illustration purposes to illustrate a wiring diagram;

FIG. 13 is a side elevational view of the system component of FIG. 12;

FIG. 14 is a rear elevational view of the system component of FIG. 12;

FIG. 15 is a pictorial view of the compact electronic component system of FIG. 1 illustrating it partially disassembled;

FIG. 16 is a front elevational view of a system component, which is constructed in accordance with another embodiment of the invention, illustrating it with the computer components omitted for sake of clarity;

FIG. 17 is a sectional elevational view of another compact electronic system, which is constructed in accordance with yet another embodiment of the invention, illustrating an air flow path;

FIG. 18 is a vertical elevational view of the system component of FIG. 17, illustrating a different air flow path;

FIG. 19 is a vertical elevational view of the system component of FIG. 17, illustrating another air flow path;

FIG. 20 is a vertical elevational view of the system component of FIG. 17, illustrating a still further air flow path;

FIG. 21 is a diagrammatic pictorial view of a further compact electronic component system, which is constructed in accordance with a still further embodiment of the present invention, and which is illustrated being used in a stand alone configuration;

FIG. 22 is a plan diagrammatic view of the system of FIG. 21, illustrating it with its top wall omitted to show its internal fans;

FIG. 23 is a diagrammatic pictorial view of a component of a system of FIG. 21;

FIGS. 24 and 25 are schematic circuit diagrams for the system of FIG. 21;

FIGS. 26 and 27 are fragmentary pictorial views of detachable rack mounts for the system of FIG. 21; and

FIG. 28 is a diagrammatic front elevational view of the system of FIG. 21, illustrating it mounted in a rack.

### DETAILED DESCRIPTION OF CERTAIN EMBODIMENTS OF THE INVENTION

According to certain embodiments of the invention, there is provided a compact electronic component system which is convenient to assemble and use. According to the disclosed embodiments, the system includes vertically mounted computer components such as computer processors, computer memory or the like. The disclosed system includes compact electronic component equipment or unit, which can be mounted to a rack, or used in a stand-alone manner by itself or in combination with similar units in accordance with the embodiments of the invention.

According to one of the disclosed embodiments of the invention, a compact electronic computer unit is provided and includes a frame having rack mounts for connection with a rack, and adapted to store a plurality of electronic components, which are supported within the frame in a generally upright disposition in a side-by-side configuration.

According to other disclosed embodiments of the invention, the system includes a modular compact computer unit for use in a rack or in a stand-alone configuration. The modular compact computer unit includes a frame with rack mounts for attaching the frame to a rack. The system further includes at least one plenum. The plenum also has rack mounts for attaching the plenum to the rack. The plenum may also include a fan for cooling vertically mounted computer components mounted within the frame. The fan may be disposed internally within the frame or enclosed in a fan compartment where the fan compartment is operatively combined with a plenum unit. Rack mounts may be disposed on the fan compartment for connection to a rack.

In another disclosed embodiment of the invention, a first modular compact computer unit may be stacked onto a second modular compact computer unit. An intermediate fan unit may be placed between the first and the second modular compact computer units. The assembly of two computer units and intermediate fan unit may be operated in a stand-alone configuration or, optionally, mounted to a rack using the rack mounts provided on the modular compact computer units and intermediate fan unit.

In yet another disclosed embodiment of the invention, a separate plenum, a separate fan unit, and a combination plenum and fan unit may contain rack mounts for attachment to a rack.

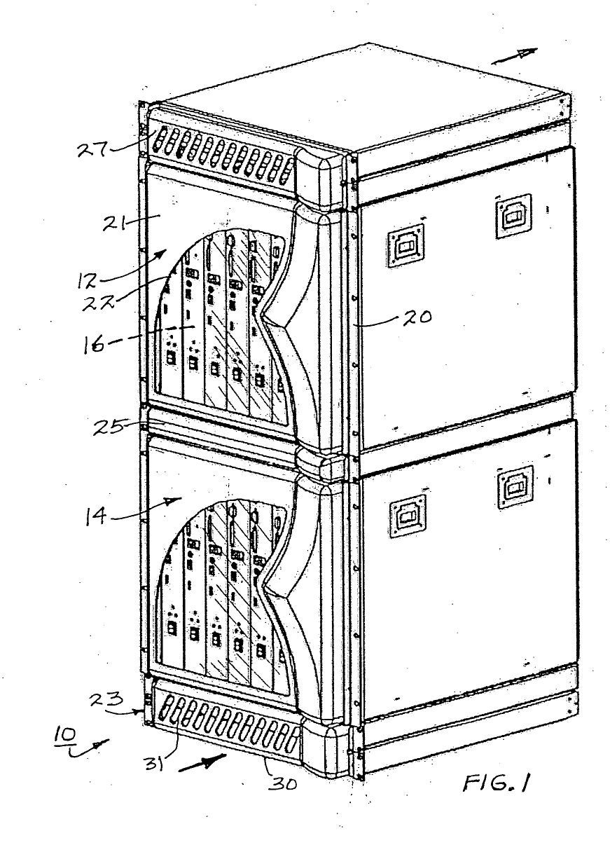

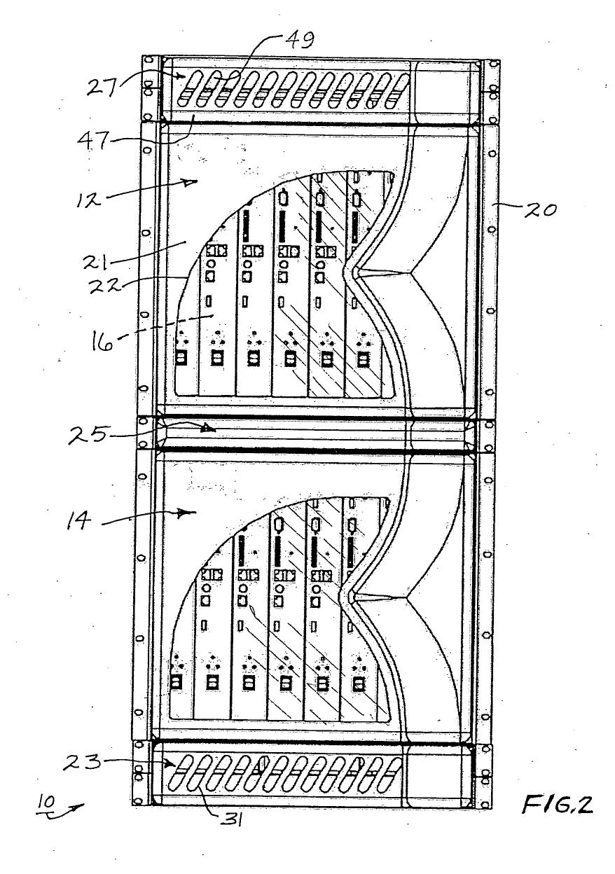

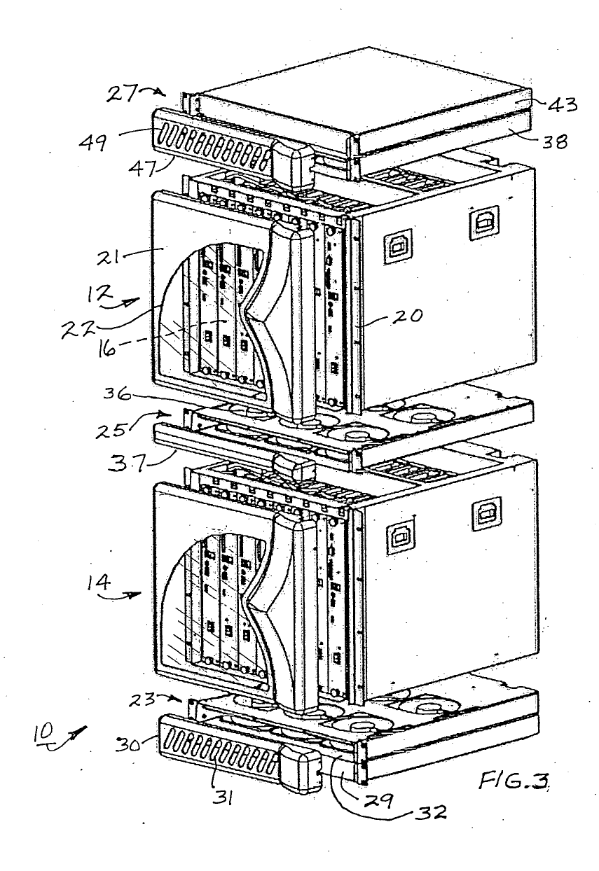

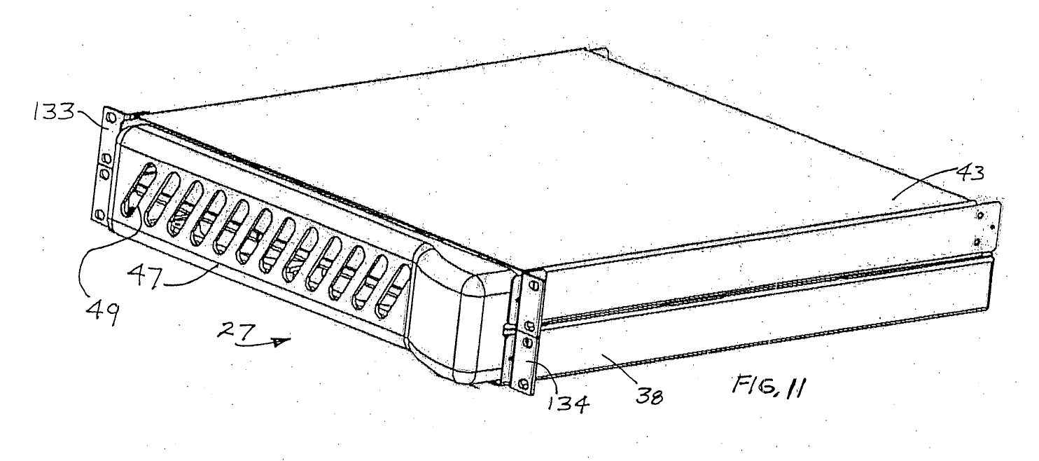

Referring now to the drawings, and more particularly to FIGS. 1-15 thereof, there is shown a compact electronic component equipment system 10, which is constructed in accordance with an embodiment of the invention. According to a disclosed embodiment of the invention, the system 10 includes a compact electronic component unit 12, which is adapted to be rack mounted above or below one or more similar units such as another compact electronic component unit 14. Either the unit 12 or the unit 14 may be used mounted to a conventional rack, or used in a stand alone configuration by resting on a support surface such as the floor.

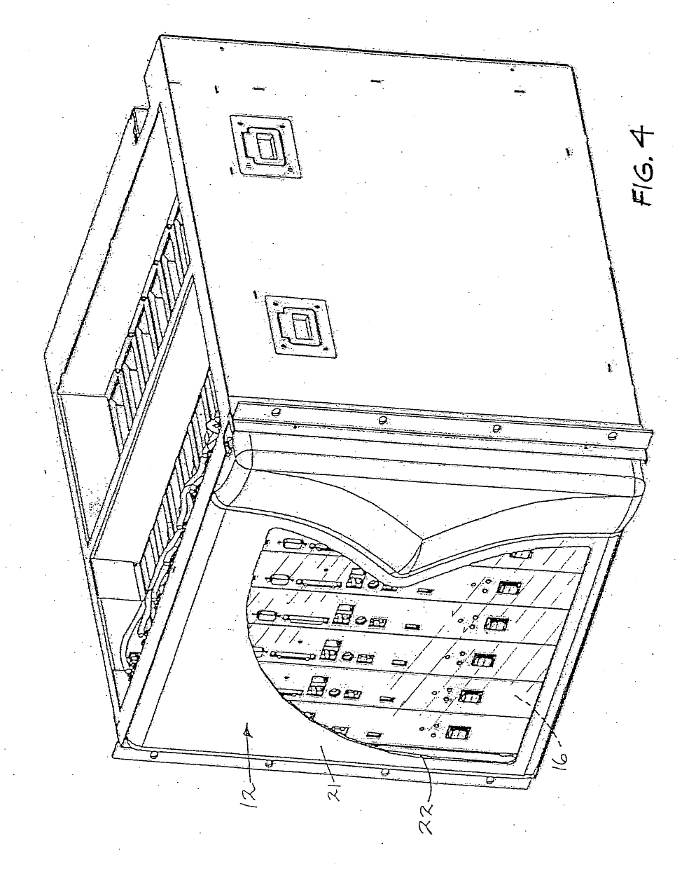

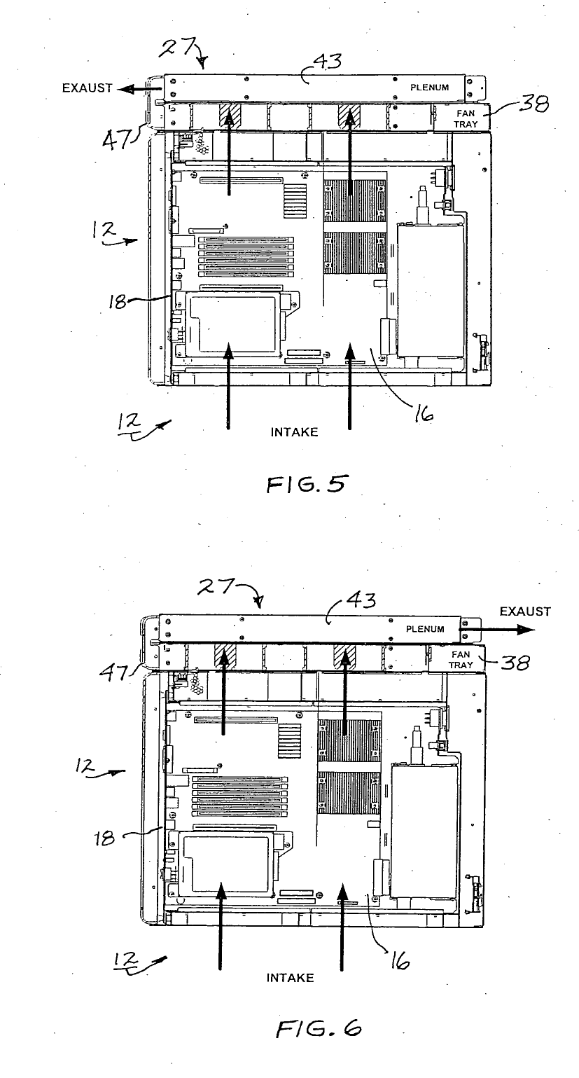

Considering now the unit 12 in greater detail, the unit 12 is similar to the unit 14, and houses a series of electronic components, such as a computer component 16 in a generally upright side-by-side configuration within an open frame 18 (FIGS. 5 and 6) having perforated side flanges or rack mounting members such as rack mount 20 (FIG. 1).

The computer component 16, may be in the form of a super computer node, which cooperates with the other similar computer components mounted within the component unit 12 to form a super computer cluster. Some of the computer components within the component unit 12 may be memory devices so that the component unit 12 may serve as a self-contained supercomputer. However, it is to be understood that there may be various different components used within the component units for other applications.

As shown in FIG. 1, the unit 12 includes a vertical front panel 21 which includes a window 22 to enclose the computer components within the frame 18. The window 22 permits visual inspection of the components mounted within the unit 12.

With reference to FIGS. 1, 5 and 6, the airflow path through the system 10 will now be considered. The air flow path is generally in the vertical direction past the generally vertically mounted computer components such as the computer component 16. In one form of the invention as disclosed herein, and as indicated by the arrows in FIG. 1, the air enters horizontally at the bottom front of the system 10 and then travels vertically upwardly through the units 12 and 14 and exits at the upper rear portion on the system 10. A bottom fan and plenum unit 23 draws air horizontally into the system 10 and then directs it upwardly through the system 10. An intermediate fan unit 25 (FIG. 1) is disposed between the component units 12 and 14 to facilitate the upwardly directed vertical air flow path to a top fan and plenum unit 27. From there, the air exhausts horizontally to the rear of the system 10.

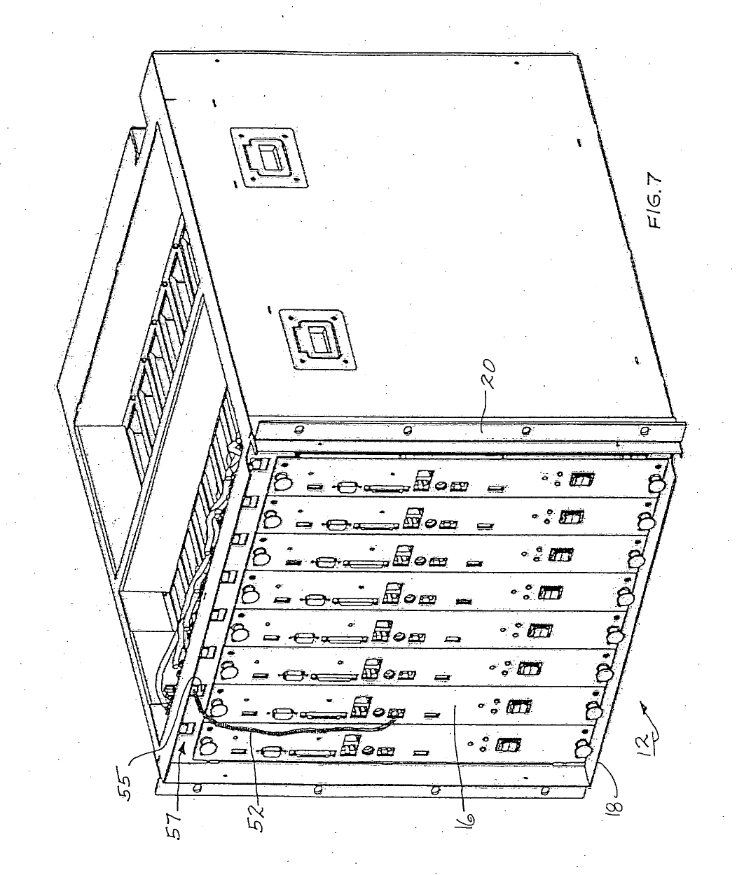

Considering now the fan and plenum bottom unit 23 in greater detail as best viewed in FIGS. 8 and 9, the bottom unit 23 includes a reversible plenum 29. Air is drawn into the plenum 29 through a perforated front plate 30 (FIG. 1), into an opening or mouth 31 of the plenum 29. As hereinafter described in greater detail, the plenum 29 is reversible and can be positioned such that the opening or mouth 31 is facing to the rear of the bottom unit 23 so that air can be drawn into the system 10 from the rear thereof as an alternative path of travel for the air.

The bottom unit 23 includes a fan compartment 32 mounted above the plenum 29 and includes a group of fans such as a fan 34 positioned to exhaust air from the plenum 29 and direct it upwardly into the bottom of the unit 14. The bottom unit 23 also includes rack mounts 130 and 131 for mounting the bottom unit 23 on a rack (not shown). The rack mounts may be detachable, and may be in the form of L brackets bolted to the opposite sides of the front of the bottom unit 23. the mounts may be removed when the unit such as the unit 14 is used in a stand along configuration.

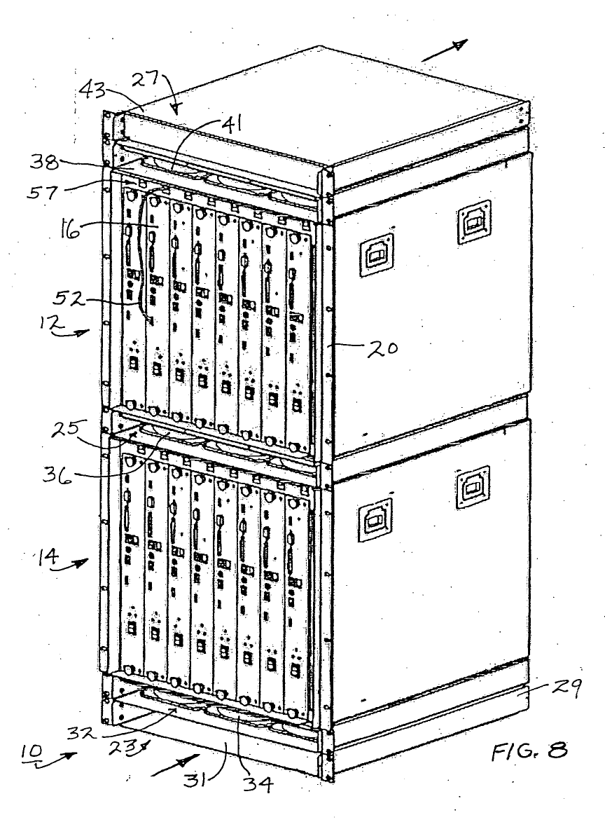

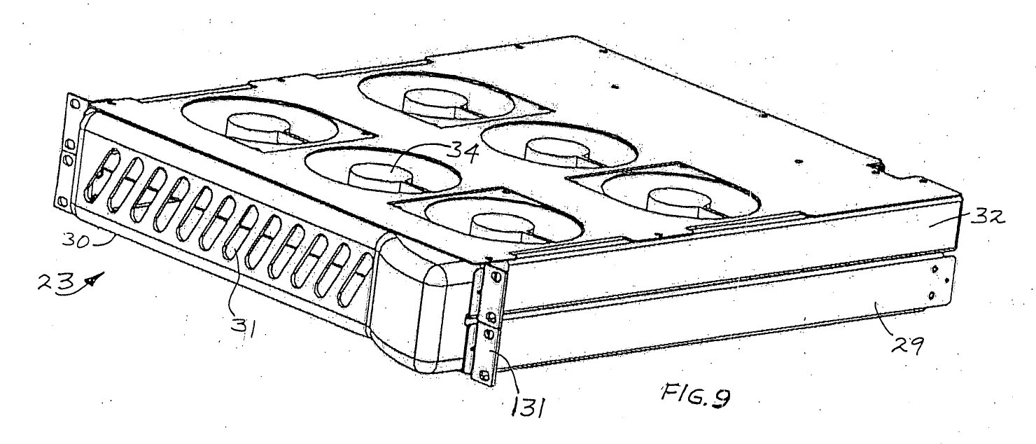

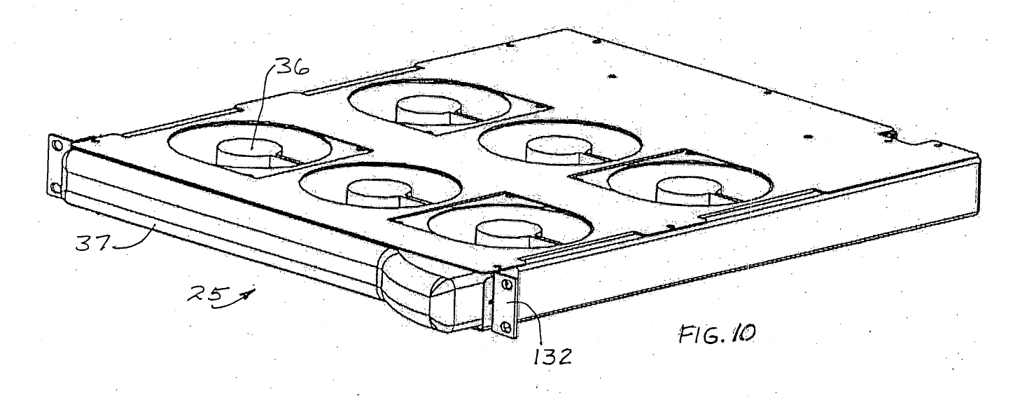

Considering now the intermediate fan unit 25 in greater detail as best viewed in FIGS. 8 and 10, the fan unit 25 includes a group of fans such as a fan 36 and has a front opaque plate 37 (FIG. 10). The fans direct the air from the upper portion of the lower component unit 14 and into the bottom portion of the upper component unit 12. The fan unit 36 also contains rack mounts 132 for mounting the fan unit 25 to a rack (not shown) and may be similar to the bottom unit rack mounts 131.

Considering now the top fan and plenum unit 27 in greater detail as best viewed in FIGS. 8 and 11, the unit 27 is generally similar to the bottom unit 23, and includes a fan compartment 38, including a group of fans such as a fan 41 as best seen in FIG. 8. The unit 27 also includes a plenum 43 which directs the airflow vertically from the fans and then directs it rearwardly horizontally from the system 10. The plenum 43 is also reversible so that air can be directed alternatively from the fans such as the fan 41 through a perforated front plate 47, having a series of openings such as an opening 49 to exhaust the air from the system 10 through the front thereof. The top fan and plenum unit 27 also contains rack mounts 133 and 134 for mounting the top fan and plenum unit to a rack (not shown).

Considering now the cabling for the system 10 with reference to FIGS. 7, 8, 12, 13 and 14, external cables such as a cable 52 (FIGS. 7 and 8) interconnect the computer components to a set of horizontally spaced-apart frame data sockets 55 (FIG. 7). In this regard, for example, the cable 52 interconnects the computer data socket 53 and a frame data socket 55 (FIGS. 7 and 12) of the series of front frame data sockets 57.

As best seen in FIG. 12, the front frame data sockets 57 are interconnected to a series of vertically spaced-apart rear frame data sockets 59 by means of a group of cables generally indicated at 62. For example, a cable 64 interconnects the frame data socket 55 of the front data sockets 57 with a rear data socket 66 of the rear data sockets 59. The rear data sockets 59 can be interconnected with other units such as a switch (not shown). Thus, the entire component units 12 are self-contained, and can be readily mounted to a rack (not shown) by means of the rack mounts such as rack mount 20. It is also to be noted that the component units such as the units 12 and 14 may be mounted either individually or in combination with one another in a stand-alone configuration, where it is not desired to be rack mounted.

Referring now to FIGS. 13 and 14, there is shown the power cables generally indicated at 68 for providing power to the system 10.

Referring now to FIG. 16, there is shown a compact electronic component equipment system 71, which is constructed in accordance with another embodiment of the invention, and which is generally similar to the system 10, except that the output data ports are located at the front of the system 71 instead of at the rear portion thereof. The system 71 includes a component unit 73 having an open frame 75. The open frame 75 includes a series of front data sockets 77 which are horizontally spaced apart in a similar manner as the sockets 57 of the system 10. A group of cables 79 interconnect the front data sockets 77 to a series of front vertically spaced-apart data sockets 82. In this manner, the group of cables 79 is readily accessible from the front of the system 71.

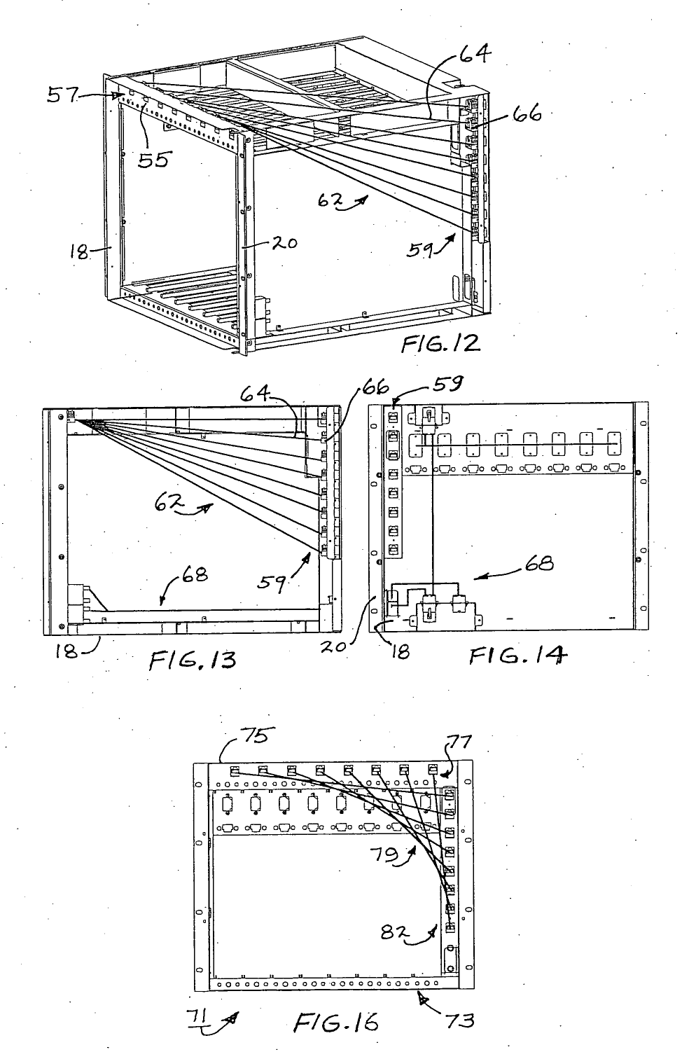

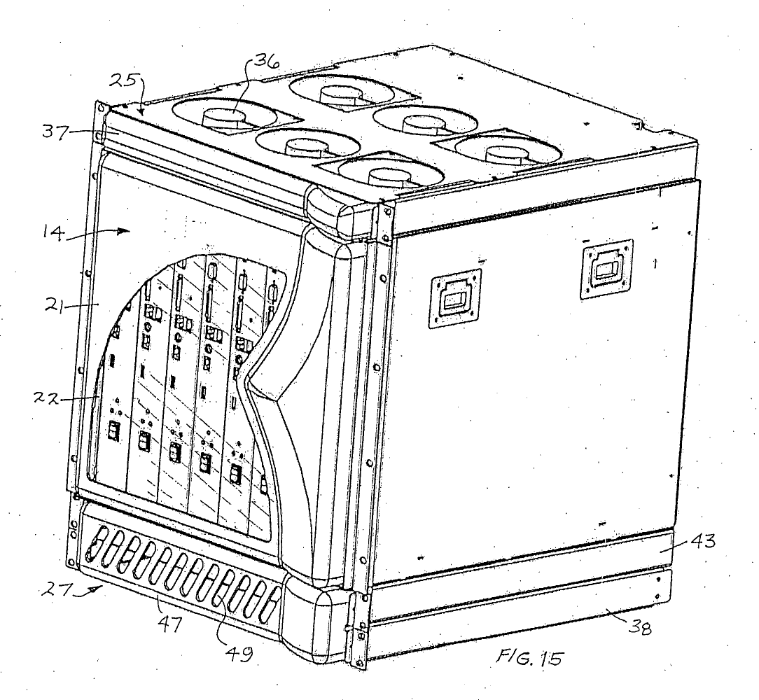

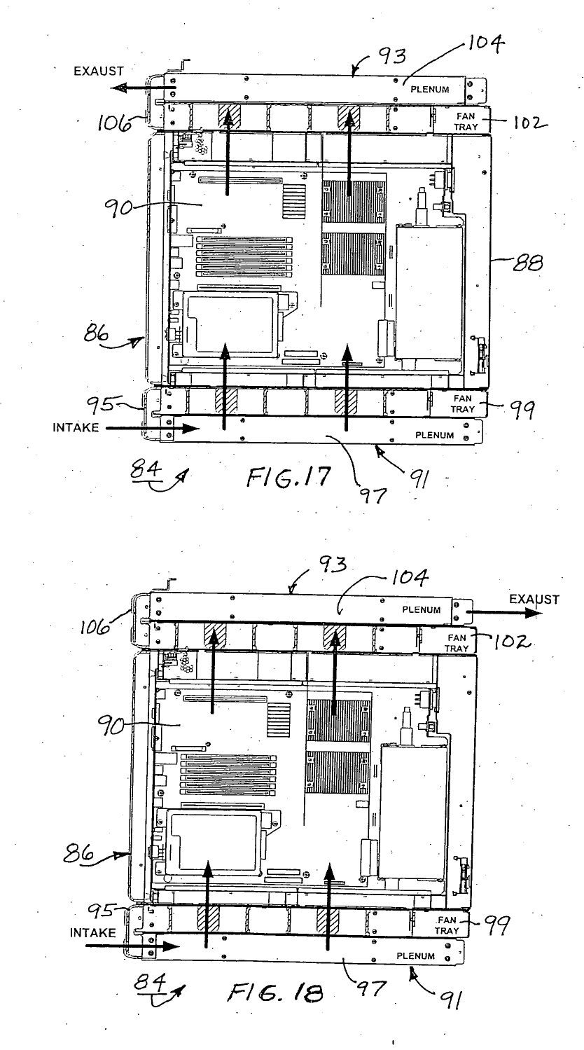

Referring now to FIGS. 17, 18, 19 and 20, there is shown a compact electronic component equipment system 84, which is constructed in accordance with yet another embodiment of the present invention. The system 84 is generally similar to the system 10, except that the system 84 includes only a single component unit and has a pair of fan and plenum units at the top and bottom thereof to enable a variety of different air flow paths as will be explained in greater detail hereinafter. The system 84 includes a component unit 86 which is generally similar to the component unit 12 of FIG. 1, and has an open frame 88 for supporting in a vertical disposition a series of electronic components such as in electronic compound 90 in a side-by-side configuration.

The system 84 includes a bottom fan and plenum unit 91 and a top fan and plenum unit 93 to direct air vertically from the bottom of the system 84 through the top thereof.

As shown in the orientation of FIG. 19, air is taken into the plenum 97 at the rear thereof and directed vertically upwardly into a bottom fan unit or tray 99. The air then flows vertically upwardly into the interior of the frame 88 past the electronic components and into a top fan unit or tray 102. A reversible plenum 104 is mounted above the fan unit 102 to direct air horizontally through a top front perforated panel 106 to permit air to exit the system,

As shown in FIG. 18, the system 84 has its plenum 104 disposed in a reversed disposition whereby the air exits the system 84 at the rear thereof. In this regard, the plenum 104 is re-positioned at 180 degrees from the position as indicated in FIG. 19.

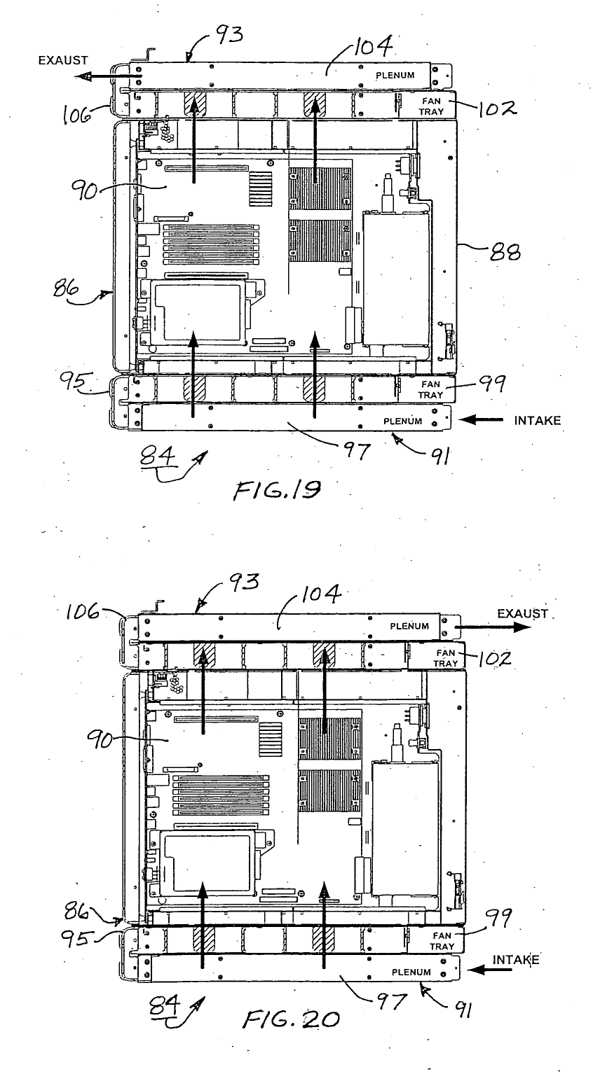

As shown in FIG. 19, the plenum 104 is positioned in a similar manner as shown in FIG. 17 to exhaust the air at the top of the system 84, and as the plenum 97 repositioned to intake the air from the front thereof through the perforated front panel 95. As shown in FIG. 20, the bottom plenum 97 is disposed in a similar manner as shown in FIG. 19 to draw air from the rear of the system 84, and has the plenum 104 disposed in a similar manner as shown in FIG. 18 to exhaust the air to the rear of the system 84.

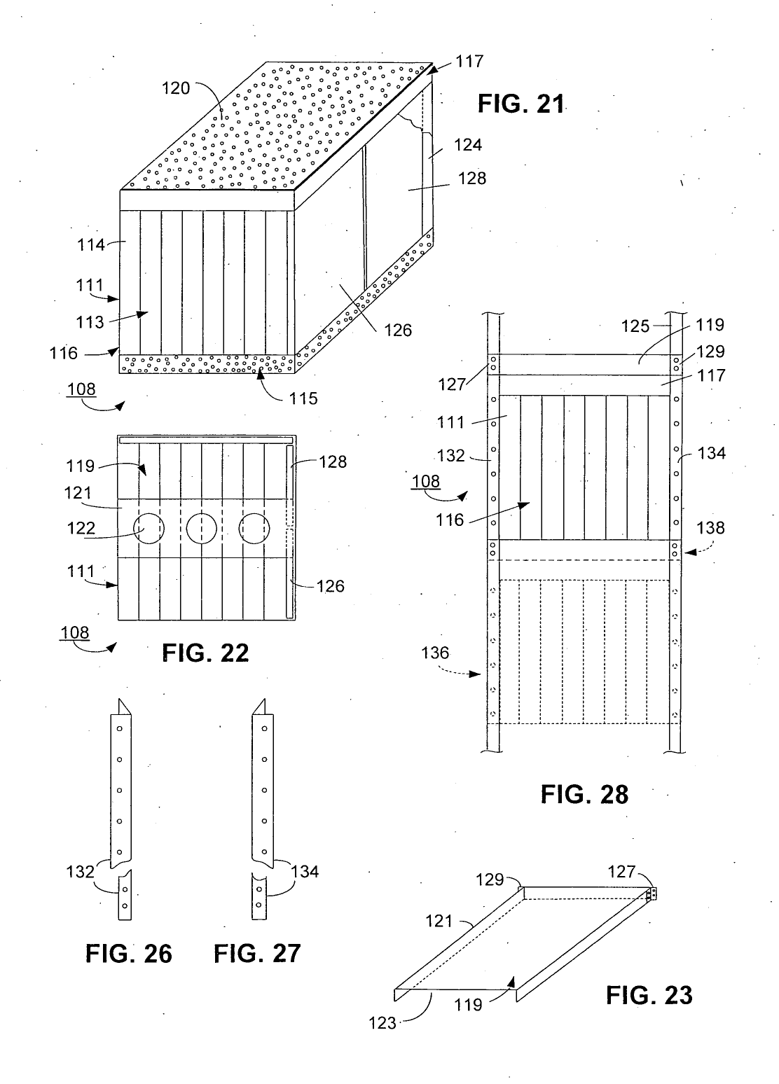

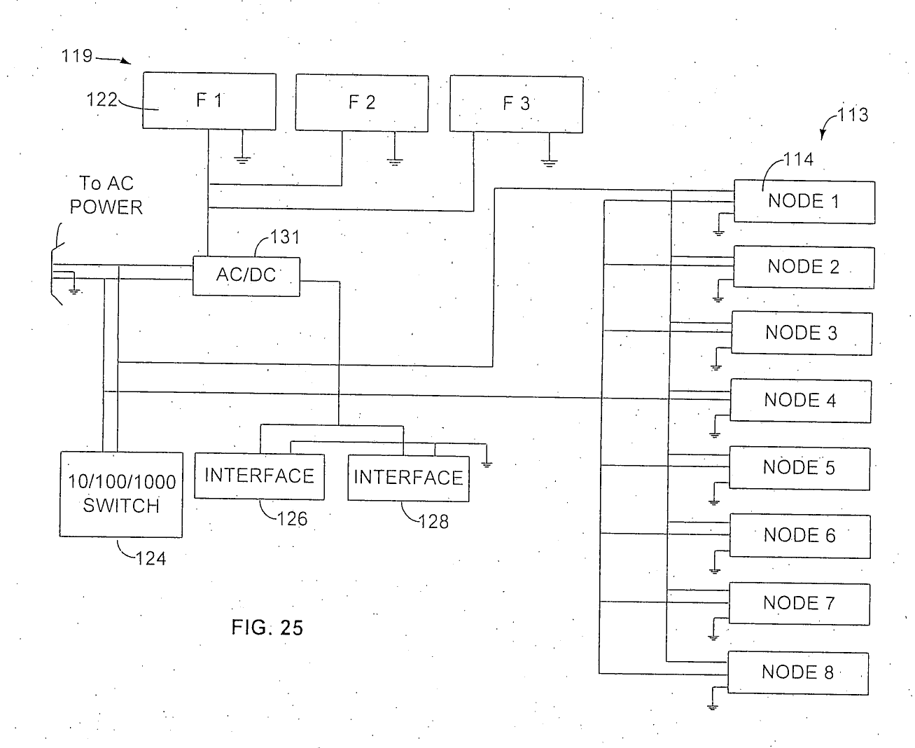

Referring now to FIGS. 21 through 25, there is shown a compact electronic component equipment system 108, which is generally similar to the system 10 of FIG. 1, except that this system 108 has an internal fan arrangement for cooling and an internal switch and high-speed interface. The system 108 generally includes a component unit 111 which is similar to the component unit 12 of FIG. 1. The unit 111 includes a series of electronic components such as nodes 113, arranged removably in an upright side-by-side configuration. According to a disclosed embodiment of the invention, the component unit 111 may be configured as a supercomputer cluster, which may be self contained, and which may be mounted as a unit in a rack as shown in FIG. 28, or alternatively can be used in a stand-alone configuration as shown in FIG. 21.

The system 108 includes an open frame 116 similar to the frame 18 of the system 10 of FIG. 1. The frame is adapted to rest on a bottom plenum unit 115 which is in the form of a hollow perforated base that admits air to the bottom of frame 116. The frame 116 also includes an integral top fan compartment 117 having mounted therein an internal fan unit generally indicated at 119 (FIG. 22) for cooling the component unit 111 and the nodes. A perforated top wall 120 covers the top of the compartment 117 to permit air to exist therefrom.

As shown in FIG. 23, the system 108 includes a plenum 119 having a channel shaped body 120 having an opaque end wall or panel 121. The plenum 119 may be employed when the component unit 111 is mounted on a rack, such as a rack 125. For this purpose, the plenum 119 includes a pair of rack mounts 127 and 129. The mount 127 is similar to the mount 129 and is similar to the mounts employed in the system 10 of FIG. 1, and may be in the form of an L bracket having holes in each leg to enable the mount to be fastened to the plenum body 120, which can then be mounted to the rack 125 (FIG. 28). In this regard, the free legs of the mounts 127 and 129 flank either side of the wall 121 and extend therefrom in the plane thereof to serve as ears or flanges to be bolted to the rack 125.

The plenum 119 includes an open end portion or mouth 123 for discharging air from the interior of the component unit 111. In this regard, the plenum 119 can be disposed where the open end portion 123 is facing either forwardly or rearwardly at the option of the user. The plenum 119 may be composed of any suitable material such as sheet metal, thermoplastic material or other suitable rigid material. If desired, in place of using the plenum 119, the perforated wall may be retained on the unit 111 when it is mounted to the rack 125 to direct the air upwardly from the unit 111.

In one embodiment of the invention, the entire system 108 may be rack mounted by utilizing rack mounts 132 and 134 which are similar to the rack mounts 20 of the system 10. When so doing, in one embodiment, the component unit 111 is 9U (standard units) high, and the plenum 119 is 1 U high, whereby the entire system 108 occupies a height of 10U.

As indicated in FIG. 28, a second compact electronic component equipment system indicated in broken lines at 136 may be mounted below (or above) rack mounted system 108 on the same rack 125. A fan unit 138 may be mounted to the rack 125 between the systems 108 and 136. The fan unit 138 may be similar to the fan unit 25 of FIG. 1. Further compact systems and components (not shown) may be mounted to the rack 125 in alignment with the systems 108 and 136 where a vertical air flow may be directed through the rack-mounted, vertically aligned systems and components.

For cooling purposes, the internal fan unit 119 includes a series of fans such as a fan 122 for moving air vertically upwardly through the interior of the component unit 111. The internal fan unit 119 is mounted at the upper end of the component unit 111. However, it is to be understood that the internal fan unit could be mounted at other locations within the component unit 111.

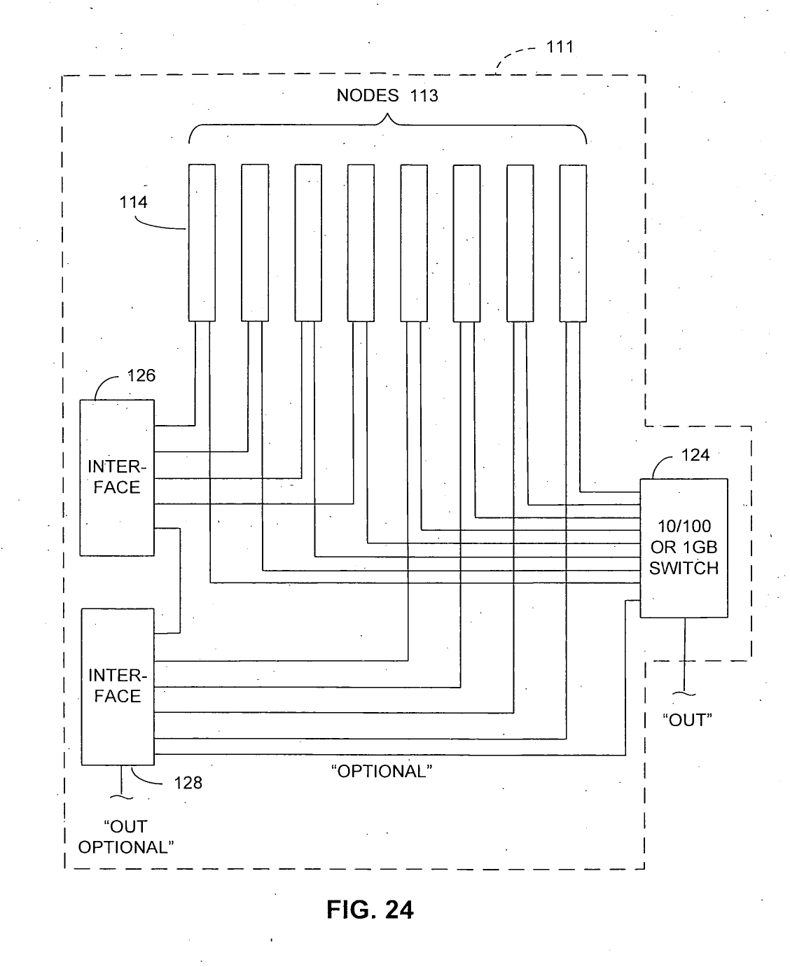

As indicated in FIG. 22, a 10/100, or 1 GB switch unit 124 is mounted at the rear portion of the component unit 111 and is connected electrically to nodes 113 such as the node 114 for switching therebetween. Additionally, a pair of interfaces 126 and 128 are mounted in a side-by-side configuration as indicated in FIGS. 21 and 22 to provide a high speed interface for the nodes such as the node 114. As indicated in FIG. 24, there are a total of eight nodes as indicated at 113 in the disclosed embodiment of the invention. Each one of the nodes is connected to the switch 124 for communicating with other external computers or other systems via networks.

The interfaces 126 may be provided to enable the nodes 113 to communicate with one another internally at a high rate of speed, and also can communicate through an optional connection to the switch 124 for communicating externally. The interfaces 126 and 128 are connected together to form one larger size interface, and the interface 128 is able to have an external port via a lead OUT optional to a similar interface equipped network. According to one embodiment of the invention, the interfaces 126 and 128 may be an high speed interconnect sold under the trade name “INFINIBAND”, marketed by DivergeNet, Inc., having a place of business in San Jose, Calif.

While the present embodiments of the invention as disclosed herein have been particularly shown and described with reference to particular embodiments thereof, it will be understood by those skilled in the art that various changes in form and details may be made therein without departing from the true spirit and scope of the accompanying claims.

What is claimed is:

1. A modular compact computer system having a plurality of vertically oriented computer components used either in a rack or stand alone, comprising:
a computer component support frame;
the frame having a set of frame rack mounts for attaching the frame to the rack;
at least one unit and at least one fan unit for directing air into and out of the frame; and
each one of the units having unit rack mounts attached thereto for affixing its unit to the rack.

2. A modular compact computer system as recited in claim 1, further including a second modular compact computer unit having
a second computer component support frame;
the second frame having a set of second frame rack mounts for attaching the second frame to the rack;
at least one second plenum unit at least one second fan unit; and
each one of the units having unit rack mounts attached thereto for affixing its second unit to the rack so that the frame and units are mounted in vertical alignment.

3. A modular compact computer system as recited in claim 1, further including a switch circuit electrically connected to the computer components.

4. A modular compact computer system as recited in claim 1, further comprising an interface circuit for providing a high speed interface for the computer components.

5. A modular compact computer system as recited in claim 4, further including a second interface circuit, the second interface circuit electrically connected to the first mentioned interface circuit.

6. A modular compact computer system as recited in claim 1, further including
a horizontal set of frame data sockets being disposed on the frame; and
a vertical set of frame data sockets being disposed on the frame.

7. A modular compact computer system as recited in claim 6, wherein the horizontal and vertical sets of frame data sockets are electrically interconnected.

8. A modular compact computer system as recited in claim 7, wherein at least one frame data socket of the horizontal set of frame data sockets is directly electronically connected to at least one frame data socket of the vertical set of frame data sockets.

9. A modular compact computer unit having a plurality of vertically mounted computer components used either in a rack or stand alone, comprising:
a computer component support frame; and
the frame having a set of detachable frame rack mounts for attaching the frame to the rack.

10. A modular compact computer unit as recited in claim 1, further including a perforated base for supporting the frame from below.

11. A modular compact computer system having a plurality of vertically mounted computer components used either in a rack or stand alone, comprising:
a computer component support frame;
the frame having a set of frame rack mounts for attaching the frame to the rack;
a fan disposed within the frame;
at least one plenum; and
each one of the set of plenums having plenum rack mounts attached thereto for attaching the plenum to the rack.

12. A modular compact computer system as recited in claim 1, further including a second modular compact computer unit having
a second computer component support frame;
the second frame having a set of second frame rack mounts for attaching the second frame to the rack;
a second pair of plenums; and
each one of the second set of plenums having plenum rack mounts attached thereto for attaching the plenum to the rack.
An intermediate fan unit having an upper portion and a lower portion;
the first modular compact computer unit being attached to the upper portion of the intermediate fan unit;
the second modular compact computer unit being attached to the lower portion of the intermediate fan unit.

13. A plenum for use with a modular compact computer unit comprising a channel shaped body including an open end portion for permitting the discharge of air from the interior of the plenum or for permitting air to be drawn into the plenum.

14. A plenum as recited in claim 13, wherein the plenum is formed of a rigid material.

15. A plenum as recited in claim 13, wherein the plenum has plenum rack mounts attached thereto.

16. A plenum-fan unit for use with a modular compact computer unit, comprising:
a plenum having a channel shaped body;
a fan compartment mounted in operative relationship to the plenum for exhausting air from or into the plenum;
at least one fan mounted in the fan compartment.

17. A plenum-fan unit as recited in claim 16, wherein the plenum has plenum rack mounts attached thereto.

18. A fan unit for use with a modular compact computer unit, comprising:
a fan compartment; and
at least one fan mounted in the fan compartment for creating air movement.

19. A fan unit as recited in claim 18, wherein the plenum has fan tray rack mounts attached thereto.

20. A method of using a modular compact computer unit having a plurality of vertically mounted computer components used either in a rack or stand alone, comprising:
disposing the computer component unit on a perforated base to enable the unit to be used stand alone; and
alternatively, mounting the modular compact computer unit on a rack.

21. A method of using a modular compact computer unit having a plurality of vertically mounted computer components used either in a rack or stand alone, comprising:
mounting a first modular compact computer unit on a rack;
mounting an intermediate fan unit on a rack in vertical alignment with the first modular compact computer in operative connection thereto; and
mounting a second modular compact computer unit on the rack in vertical alignment with the intermediate fan unit and the first modular unit.
